(19) United States
(12) Patent Application Publication
(10) Pub. No.: US 2024/0263340 A1
(43) Pub. Date: Aug. 8, 2024

(54) METHOD OF GROWING CRYSTAL

(71) Applicant: Nippon Telegraph and Telephone Corporation, Tokyo (JP)

(72) Inventors: Sohan Kawamura, Tokyo (JP); Eiko Sato, Tokyo (JP); Takashi Sakamoto, Tokyo (JP); Soichi Oka, Tokyo (JP)

(21) Appl. No.: 18/557,463

(22) PCT Filed: May 24, 2021
(86) PCT No.: PCT/JP2021/019517

§ 371 Date: Oct. 26, 2023

(51) Int. Cl. C30B 13/24; C30B 13/32

(52) U.S. Cl. CPC C30B 13/24; C30B 13/32

(57) ABSTRACT

An embodiment crystal growing apparatus is an apparatus that grows a crystal of a raw material by heating and melting, with a heating mechanism, one end side of a raw material body formed with a solid raw material with which a seed crystal is in contact, and further includes a laser mechanism. In crystal growth using this crystal growing apparatus, the portion to be heated for forming a melt is moved in the direction toward the other end side of the raw material body, and the melt is irradiated and heated with laser light emitted from the laser mechanism while the melt is moved from the one end side to the other end side.

### CROSS-REFERENCE TO RELATED APPLICATIONS

This application is a national phase entry of PCT Application No. PCT/JP2021/019517, filed on May 24, 2021, which application is hereby incorporated herein by reference.

### TECHNICAL FIELD

The present invention relates to a crystal growing apparatus.

### BACKGROUND

As disclosed in Patent Literature 1 and Patent Literature 2, there are methods for growing a single crystal having a uniform composition by reducing changes in the composition of a melt or the concentration of impurities in the melt in a case where the composition of the melt or the concentration of impurities in the melt changes with the growth of the crystal.

### CITATION LIST

### Patent Literature

Patent Literature 1: JP 2013-126941 A
Patent Literature 2: JP 2005-008427 A

### SUMMARY

### Technical Problem

By the above techniques, however, the intended composition of the single crystal differs from the intended composition of the melt, and therefore, the composition distribution of the melt changes in the crystal growth direction. For this reason, depending on the temperature gradient of the solid-liquid interface, compositional supercooling that is supercooling due to a change in the composition distribution occurs, and therefore, it is difficult to grow a crystal having a desired composition.

Embodiments of the present invention can solve the above problem, and the embodiments aim to enable growth of a crystal having a desired composition even when the composition of a melt or the concentration of impurities in the melt changes with the growth of the crystal.

### Solution to Problem

A crystal growing apparatus according to embodiments of the present invention is a crystal growing apparatus that grows a crystal of a raw material by: heating and melting one end side of a raw material body with a heating mechanism, the raw material body being formed with the raw material that is solid, the one end side of the raw material body being contacted by a seed crystal; and moving a portion to be heated in the direction toward another end side of the raw material body, to move the portion in which the raw material body is melted from the one end side to the another end side, the crystal of the raw material being grown in the direction from the portion with which the seed crystal is in contact toward the another end side. The crystal growing apparatus includes a laser mechanism that irradiates and heats, with laser light, the portion in which the raw material body is melted near a boundary region between the portion in which the raw material body is melted and the crystal.

### Advantageous Effects of Embodiments of the Invention

As described above, according to embodiments of the present invention, a laser mechanism for irradiating and heating, with laser light, a portion in which a raw material body is melted near a boundary region between the portion in which the raw material body is melted and a crystal is provided. Thus, a crystal having a desired composition can be grown even if the composition of the melt or the concentration of impurities in the melt changes with the growth of the crystal.

### BRIEF DESCRIPTION OF THE DRAWINGS

FIG. 1A is a configuration diagram illustrating the configuration of a crystal growing apparatus according to a first embodiment of the present invention.

FIG. 1B is a perspective view of part of the configuration of the crystal growing apparatus according to the first embodiment of the present invention.

FIG. 2A is a configuration diagram illustrating the configuration of a crystal growing apparatus according to a second embodiment of the present invention.

FIG. 2B is a perspective view of part of the configuration of the crystal growing apparatus according to the second embodiment of the present invention.

FIG. 3A is a configuration diagram illustrating the configuration of a crystal growing apparatus according to a third embodiment of the present invention.

FIG. 3B is a perspective view of part of the configuration of the crystal growing apparatus according to the third embodiment of the present invention.

### DETAILED DESCRIPTION OF ILLUSTRATIVE EMBODIMENTS

The following is a description of a crystal growing apparatus according to embodiments of the present invention.

### First Embodiment

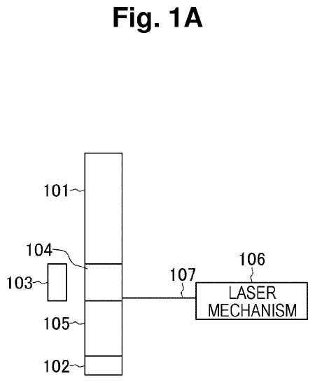

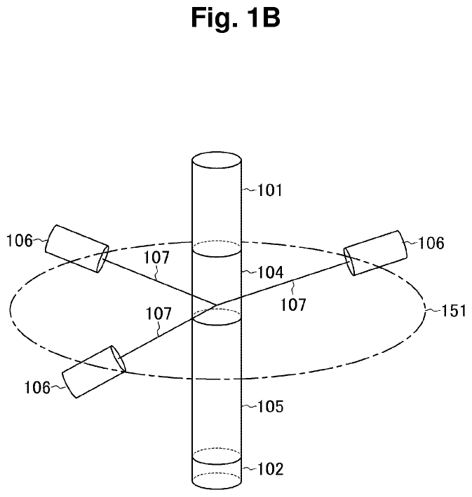

First, a crystal growing apparatus according to a first embodiment of the present invention is described with reference to FIGS. 1A and 1B.

This crystal growing apparatus is an apparatus that grows a crystal 105 of a raw material by heating and melting, with a heating mechanism 103, one end side of a raw material body 101 formed with a solid raw material with which a seed crystal 102 is in contact, and further includes a laser mechanism 106. The raw material body 101 has a rod-like shape, for example. The heating mechanism 103 heats a desired portion by a heating method using induction heating, resistance heating, a xenon lamp, or the like, for example. The heating mechanism 103 is disposed so as to surround the periphery of the raw material body 101, for example.

A plurality of the laser mechanisms 106 can be disposed so as to surround the periphery of the raw material body 101. Also, the plurality of the laser mechanisms 106 can be disposed so that emitted laser light 107 passes over a first plane 151 perpendicular to the direction from one end side toward the other end side of the raw material body 101. In this case, each laser mechanism of the plurality of the laser mechanisms 106 is preferably disposed at a position other than the optical path of the laser light 107 emitted from another laser mechanism 106.

By a floating zone melting method (floating zone method) or a Bridgman method using this crystal growing apparatus, crystal growth can be conducted as described below. First, one end side of the raw material body 101 with which the seed crystal 102 is in contact is heated and melted by the heating mechanism 103, to form a melt 104. The portion to be heated is then moved toward the other end side of the raw material body 101, so that the portion in which the raw material body 101 is melted (the melt 104) is moved in a direction from the one end side toward the other end side. As a result, the crystal 105 of the raw material is grown in the direction from the portion with which the seed crystal 102 is in contact, toward the other end side. In the process of growing a crystal in this manner, the melt 104 near the boundary region between the melt 104 and the crystal 105, where the raw material body 101 is melted, is irradiated and heated with the laser light 107 emitted from the laser mechanism 106.

With the crystal growing apparatus according to the first embodiment described above, the temperature gradient from the melt 104 to the crystal 105 in the boundary region (interface) between the melt 104 and the crystal 105 can be made even greater with the use of the laser mechanism 106. As the laser mechanism 106 is used, the temperature gradient in the boundary region between the crystal 105 and the melt 104 can be made greater in accordance with the composition distribution in the crystal growth direction.

In a case where a single crystal of a substance that decomposes and melts as described on pages 66 and 67 of Reference Literature 1 or a substance showing a phase diagram as shown on pages 71 and 72 of Reference Literature 1 is grown by a floating zone melting method, a Bridgman method, or the like, the composition of the melt changes with the growth of the crystal 105, and therefore, a composition distribution of the melt 104 appears in the growth direction of the crystal 105.

According to pages 82 and 83 of Reference Literature 1, in a case where such a composition distribution appears, when the temperature gradient in the growth direction in the boundary region between the crystal 105 and the melt 104 is small, compositional supercooling occurs, and crystal growth proceeds in a cellular manner. Therefore, a single crystal of desired quality might not be obtained.

To reduce such compositional supercooling, local heating is performed by irradiation with the laser light 107 from the laser mechanism 106, so that the above-described temperature gradient is made greater. For example, the raw material body 101 is normally melted with the heating mechanism 103 performing resistance heating, and the seed crystal 102 is moved in a direction (one end side) opposite to the growth direction (the other end side) of the crystal 105, to grow the crystal 105. However, the composition of the melt 104 changes with this growth.

Therefore, the composition of the boundary region (interface) between the crystal 105 and the melt 104 differs from the composition of the boundary region between the raw material body 101 and the melt 104, and a composition distribution appears in the crystal growth direction. The differential value in the boundary region between the crystal 105 and the melt 104 in this composition distribution depends on the composition of the single crystal to be obtained and the composition of the raw material body 101, and changes reflecting the concentration dependence of the liquidus line in the phase diagram of the raw material composition.

Accordingly, in a case where a substance as described on pages 66 and 67 of Reference Literature 1 or a substance shown in the phase diagram as shown on pages 71 and 72 of Reference Literature 1 is the target, the differential value of the composition distribution in the boundary region between the crystal 105 and the melt 104 described above also changes with the growth of the crystal 105, and the temperature gradient necessary for avoiding compositional supercooling in the boundary region also changes.

For example, irradiation is performed while the power of the laser light 107 is increased with the grown length of the crystal 105, so that the temperature gradient in the boundary region between the crystal 105 and the melt 104 can be made greater in accordance with the composition distribution that appears in the crystal growth direction in the melt 104 with the growth of the crystal 105, and the long crystal 105 can be grown while compositional supercooling is avoided.

Here, the upper limit of the temperature gradient that can be formed can be made greater with the use of a plurality of laser mechanisms 106. However, part of the energy of the laser light 107 of each laser mechanism of the plurality of laser mechanisms 106 is transmitted through the melt 104. In a case where the transmitted energy is 0.5% or more of the energy that has entered the melt 104, for example, a failure might occur in another laser mechanism 106. To prevent such a failure of a laser mechanism 106, each laser mechanism of the plurality of the laser mechanisms 106 is preferably disposed at a position other than the optical path of the laser light 107 emitted from another laser mechanism 106.

For example, the plurality of laser mechanisms 106 is disposed so that the angle between two virtual straight lines selected as appropriate from among n virtual straight lines formed by the laser light 107 emitted from each of n laser mechanisms 106 does not become 180 degrees.

Using the laser mechanism 106 as the heating mechanism 103, it is possible to reduce the volume of the crystal growing apparatus while achieving a high energy conversion efficiency as described below.

By a floating zone melting method using resistance heating or a xenon lamp, and a Bridgman method using resistance heating, the proportion of energy to be converted into heat out of the energy that has entered the apparatus is about 30% at maximum. Further, up to about 30% of the energy converted to heat is applied to the melt in the process of growing the crystal.

For example, where the energy necessary for resistance heating is represented by Win, and the energy with which the melt is irradiated is represented by Wout, the energy conversion efficiency expressed by Wout/Win is about 9%. Normally, in a case where the rated power is A kW, the volume of the above apparatus is about A³/m³.

On the other hand, according to Reference Literature 2, in a case where a laser mechanism is used, up to about 40% out of the energy necessary for emitting laser light is converted into laser light. Also, since laser light has high directivity, almost 100% of the energy of the laser light can be applied to the melt. Where the energy entering the laser light source is represented by Win, and the energy to be applied to the melt is represented by Wout, the conversion efficiency Wout/Win is about 40%, and an energy conversion efficiency about four times higher than that with a xenon lamp or resistance heating can be achieved.

Further, in a case where the rated power of a laser mechanism is A kW, the volume of the laser mechanism is about A³/25 m³, and it can be expected that the volume of the apparatus can be reduced to A³/8 m³. Accordingly, in a case where the heating mechanism is a laser mechanism, and heating is performed only with the laser mechanism, the energy conversion efficiency can be made higher, and the volume of the apparatus can be made smaller than those of a crystal growing apparatus using a xenon lamp or resistance heating. For example, in a case where heating is performed only with a laser mechanism, the volume of the apparatus can be reduced to about ⅛ while a high energy conversion efficiency of about 40% is achieved, compared with a crystal growing apparatus according to a floating zone melting method in which the heating mechanism includes a spheroidal mirror and a xenon lamp.

### Second Embodiment

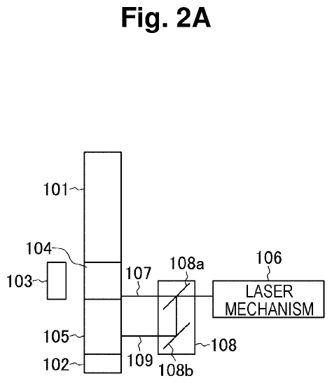

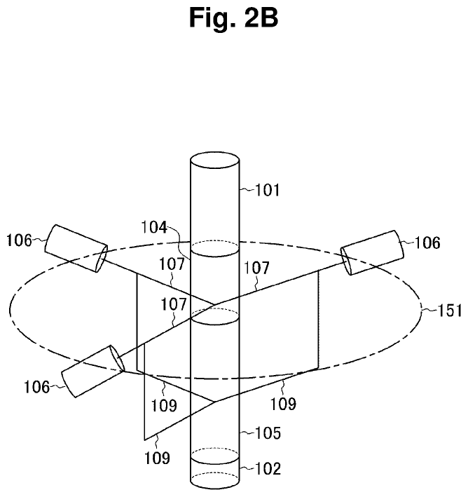

Referring next to FIGS. 2A and 2B, a crystal growing apparatus according to a second embodiment of the present invention is an apparatus that grows a crystal 105 of a raw material by heating and melting, with a heating mechanism 103, one end side of a raw material body 101 formed with a solid raw material with which a seed crystal 102 is in contact, and further includes a laser mechanism 106. These components are the same as those of the first embodiment described above.

In the second embodiment, the crystal growing apparatus further includes a separation mechanism 108 for extracting part of the laser light 107 emitted from the laser mechanism 106 and irradiating the crystal 105 with the extracted light. The separation mechanism 108 includes a semireflecting mirror 108a and a reflecting mirror 108b, for example. The laser light 107 that has entered the semireflecting mirror 108a is partially transmitted and is partially reflected. The laser light reflected by the semireflecting mirror 108a is reflected by the reflecting mirror 108b, to turn into laser light 109 with which the portion of the crystal 105 is irradiated.

By the irradiation with the laser light 109, the cooling rate of the crystal 105 is lowered, to prevent the occurrence of cracks in the crystal 105, and obtain a high-quality single crystal.

### Third Embodiment

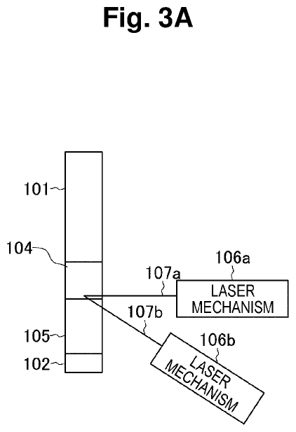

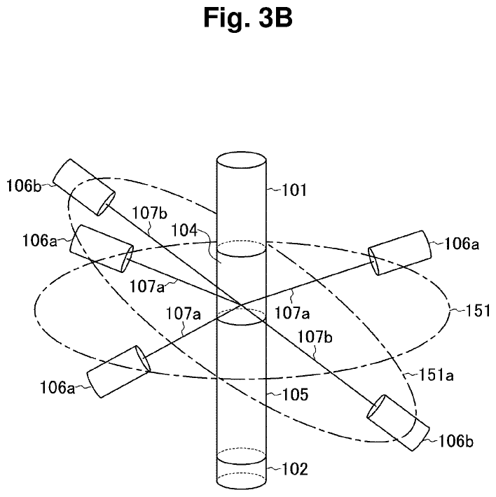

Referring next to FIGS. 3A and 3B, a crystal growing apparatus according to a third embodiment of the present invention grows a crystal 105 of a raw material by heating and melting, with a laser mechanism 106, one end side of a raw material body 101 formed with a solid raw material with which a seed crystal 102 is in contact. In the third embodiment, the heating mechanism 103 is the laser mechanism 106.

Further, in the third embodiment, each laser mechanism of a plurality of laser mechanisms 106 includes a plurality of first laser mechanisms 106a and a plurality of second laser mechanisms 106b. The plurality of first laser mechanisms 106a is designed so that emitted laser light 107a passes over a first plane 151 perpendicular to the direction from one end side toward the other end side of the raw material body 101. The plurality of second laser mechanisms 106b is designed so that emitted laser light 107b passes over a second plane 151a having a different angle from that of the first plane 151.

A melt 104 is formed by the plurality of first laser mechanisms 106a, and the temperature gradient from the melt 104 to the crystal 105 in the boundary region between the melt 104 and the crystal 105 is made greater by the plurality of second laser mechanisms 106b.

In the description below, the embodiments are explained in greater detail through Examples.

### Example 1

First, Example 1 is described. In Example 1, crystal growth was performed by a floating zone melting method using the crystal growing apparatus according to the first embodiment. The heating mechanism 103 includes two spheroidal mirrors and two xenon lamps. Also, a plurality of laser mechanisms 106 was used so that emitted laser light 107 passed over a first plane 151 perpendicular to the direction from one end side toward the other end side of the raw material body 101. Each of the laser mechanisms 106 was a CW laser having an average output of 1 kW.

Using the above configuration, single crystal growth of gadolinium pyrosilicate is performed. According to Reference Literature 3, gadolinium pyrosilicate requires growth of a crystal from a melt of a non-stoichiometric composition. Therefore, a raw material body 101 having a non-stoichiometric composition was prepared. This raw material body 101 has a rod-like shape, and its composition is constant regardless of the location.

The xenon lamp of the heating mechanism 103 was turned on, and light was condensed with a spheroidal mirror, to melt the raw material body 101 and form a melt 104. The raw material body 101 and the crystal 105 were then moved in the growth direction at a constant speed, so that crystal growth was started.

When the length of the crystal 105 in the growth direction became about 15 mm, the composition distribution of the melt 104 in the crystal growth direction changed. To avoid compositional supercooling due to this change in the composition distribution, a temperature gradient that cannot be formed through heating by the heating mechanism 103 with a xenon lamp was required.

Therefore, while the heating mechanism 103 is operated with the xenon lamp on, the laser mechanism 106 is operated to irradiate the melt 104 with the laser light 107, and the temperature of the melt 104 is raised to make the temperature gradient greater, so that compositional supercooling was avoided. As a result, the long crystal 105 was successfully grown. The temperature gradient at this time was 500° C./cm.

### Example 2

Next, Example 2 is described. In Example 2, crystal growth was performed by a Bridgman method using the crystal growing apparatus according to the second embodiment. The heating mechanism 103 is a mechanism that uses resistance heating. Also, a plurality of laser mechanisms 106 was used so that emitted laser light 107 passed through a first plane 151 perpendicular to the direction from one end side toward the other end side of the raw material body 101. Each of the laser mechanisms 106 was a CW laser having an average output of 1 kW. Note that, without the use of the separation mechanism 108, a laser mechanism like the laser mechanism 106 may be used to irradiate the crystal 105 with the laser light 109.

A potassium niobate tantalate single crystal is grown with the above configuration. A raw material body 101 of potassium niobate tantalate was melted with a heating mechanism 103 using resistance heating to form a melt 104, and crystal growth was started. In the potassium niobate tantalate, the composition of the melt 104 changes with the growth of the crystal 105, and a composition distribution appears in the growth direction of the crystal 105. Therefore, when the length of the crystal 105 becomes 15 mm, a temperature gradient necessary for avoiding compositional supercooling accompanying a change in the composition distribution that has appeared cannot be formed through heating by the heating mechanism 103, and compositional supercooling occurs.

Therefore, the laser light 107 was emitted from the laser mechanism 106, to irradiate the melt 104. Accordingly, the temperature of the melt 104 became higher, and the necessary temperature gradient was successfully formed. To anneal the crystal 105, which is a grown potassium niobate tantalate single crystal, the crystal 105 was irradiated with the laser light 109. As a result, the long crystal 105 was successfully grown while compositional supercooling was avoided. Also, the cooling rate was lowered by annealing, so that the occurrence of cracks was prevented, and the high-quality crystal 105 was successfully obtained.

### Third Embodiment

Next, Example 3 is described. In Example 3, crystal growth was performed by a floating zone melting method using the crystal growing apparatus according to the third embodiment. The plurality of first laser mechanisms 106a was designed so that emitted laser light 107a passed over the first plane 151. Also, the plurality of second laser mechanisms 106b was designed so that emitted laser light 107b passed over the second plane 151a. Further, each of the laser mechanisms was a CW laser having an average output of 1 kW.

Using the above configuration, a single crystal of gadolinium pyrosilicate is grown. A gadolinium pyrosilicate single crystal needs to be grown from a melt 104 of a non-stoichiometric composition. A raw material body 101 having a non-stoichiometric composition was prepared, and was melted by irradiation with the laser light 107a to form the melt 104, and crystal growth was started.

When the length of the crystal 105 reached 15 mm, the temperature gradient needed to be made greater. Therefore, a desired temperature gradient was formed by irradiation with the laser light 107b. As a result of further growth, it became necessary to increase the volume of the melt 104 and facilitate stirring in the melt 104, to keep the composition distribution of the melt 104 constant. Therefore, irradiation with the laser light 107a and the laser light 107b was performed to double the volume of the melt 104 and facilitate stirring. As a result, a high-quality long crystal 105 was obtained.

As described so far, according to embodiments of the present invention, a laser mechanism for irradiating and heating a portion in which a raw material body is melted near a boundary region between the portion in which the raw material body is melted and a crystal with laser light is provided. Accordingly, the temperature gradient in the boundary region between the melted portion and the crystal can be made greater, and a crystal having a desired composition can be grown even if the composition of the melt or the concentration of impurities in the melt changes with the growth of the crystal.

Note that the embodiments of the present invention are not limited to the embodiments described above, and it is obvious that many modifications and combinations can be made by those skilled in the art within the technical idea of the present invention.
Reference Literature 1: “Melt Growth Dynamics” edited by Shintaro Miyazawa, Series: Crystal growth dynamics, vol. 5, Kyoritsu Shuppan Co., Ltd., 2002.
Reference Literature 2: IPG Photonics, “YLR-U series, new ultra-compact medium power 1 μm fiber laser”, [Searched on May 12, 2021] (available at ipgphotonics.com/jp/products/lasers/mid-power-cw-fiber-lasers/1-micron/ylr-u-series).
Reference Literature 3: S. Kawamura et al., “Phase Relations around the Pyrosilicate Phase in the Gd203-Ce203-SiO2 System”, CRYSTAL GROWTH & DESIGN, vol. 9, no. 3, pp. 1470-1473, 2009.

### REFERENCE SIGNS LIST

101 raw material body
102 seed crystal
103 heating mechanism
104 melt
105 crystal
106 laser mechanism
107 laser light
108 separation mechanism
109 laser light
151 first plane

1.-5. (canceled)

6. A crystal growing apparatus for growing a crystal of a raw material, the crystal growing apparatus comprising:
a heating mechanism configured to heat and melt a raw material body comprising the raw material starting at a portion of the raw material body at a first end side of the raw material body, wherein the portion moves from the first end side to a second end side of the raw material body, wherein the first end side of the raw material body is in contact with a seed crystal, and wherein the crystal of the raw material is grown in a direction from the first end side of the raw material body to the second end side of the raw material body; and
a laser mechanism configured to irradiate and heat, with laser light, an area of the portion of the raw material body that is melted, the area being near a boundary region between the portion of the raw material body that is melted and the crystal.

7. The crystal growing apparatus according to claim 6, further comprising a plurality of the laser mechanisms disposed to surround a periphery of the raw material body.

8. The crystal growing apparatus according to claim 7, wherein each laser mechanism of the plurality of the laser mechanisms comprises:
a plurality of first laser mechanisms configured to emit a first laser light that passes over a first plane perpendicular to a direction from the first end side toward the second end side of the raw material body; and
a plurality of second laser mechanisms configured to emit a second laser light that passes over a second plane having a different angle from an angle of the first plane.

9. The crystal growing apparatus according to claim 7, wherein each laser mechanism of the plurality of the laser mechanisms is located outside an optical path of the laser light that is emitted from each other laser mechanism of the plurality of the laser mechanisms.

10. The crystal growing apparatus according to claim 6, wherein the heating mechanism comprises a spheroidal mirror and a xenon lamp.

11. The crystal growing apparatus according to claim 6, wherein the laser mechanism further comprises a separation mechanism.

12. The crystal growing apparatus according to claim 11, wherein the separation mechanism comprises a semireflecting mirror and a reflecting mirror.

13. A crystal growing apparatus for growing a crystal of a raw material, the crystal growing apparatus comprising:
a heating mechanism configured to heat and melt a raw material body comprising the raw material starting at a portion of the raw material body at a first end side of the raw material body, wherein the portion moves from the first end side to a second end side of the raw material body, wherein the first end side of the raw material body is in contact with a seed crystal, wherein the crystal of the raw material is grown in a direction from the first end side of the raw material body to the second end side of the raw material body, and wherein the heating mechanism comprises:
a laser mechanism configured to irradiate and heat, with laser light, an area of the portion of the raw material body that is melted, the area being near a boundary region between the portion of the raw material body that is melted and the crystal.

14. The crystal growing apparatus according to claim 13, further comprising a plurality of the laser mechanisms disposed to surround a periphery of the raw material body.

15. The crystal growing apparatus according to claim 14, wherein each laser mechanism of the plurality of the laser mechanisms comprises:
a plurality of first laser mechanisms configured to emit a first laser light that passes over a first plane perpendicular to a direction from the first end side toward the second end side of the raw material body; and
a plurality of second laser mechanisms configured to emit a second laser light that passes over a second plane having a different angle from an angle of the first plane.

16. The crystal growing apparatus according to claim 14, wherein each laser mechanism of the plurality of the laser mechanisms is located outside an optical path of the laser light that is emitted from each other laser mechanism of the plurality of the laser mechanisms.

17. A method for growing a crystal of a raw material, the method comprising:
heating and melting a first end side of a raw material body with a heating mechanism, the raw material body being formed with the raw material that is solid, and the first end side of the raw material body being contacted by a seed crystal; and
moving a portion to be heated in a direction toward a second end side of the raw material body, to move a portion in which the raw material body is melted from the first end side to the second end side, the crystal of the raw material being grown in a direction from the first end side toward the second end side; and
irradiating and heating, with laser light from a laser mechanism, an area of the portion in which the raw material body is melted, the area being near a boundary region between the portion in which the raw material body is melted and the crystal.

18. The method according to claim 17, further comprising disposing a plurality of the laser mechanisms to surround a periphery of the raw material body.

19. The method according to claim 18, wherein each laser mechanism of the plurality of the laser mechanisms comprises:
a plurality of first laser mechanisms that emit a first laser light that passes over a first plane perpendicular to a direction from the first end side toward the second end side of the raw material body; and
a plurality of second laser mechanisms that emit a second laser light that passes over a second plane having a different angle from an angle of the first plane.

20. The method according to claim 18, wherein each laser mechanism of the plurality of the laser mechanisms is located outside an optical path of the laser light that is emitted from each other laser mechanism of the plurality of laser mechanisms.

21. The method according to claim 17, wherein the heating mechanism comprises the laser mechanism.

22. The method according to claim 17, wherein the heating mechanism comprises a spheroidal mirror and a xenon lamp.

23. The method according to claim 17, wherein the laser mechanism further comprises a separation mechanism.

24. The method according to claim 23, wherein the separation mechanism comprises a semireflecting mirror and a reflecting mirror.
